(19) United States
(12) Patent Application Publication
(10) Pub. No.: US 2012/0108067 A1
(43) Pub. Date: May 3, 2012

(54) Edge Bead Remover For Coatings

(76) Inventors: Mark O. Neisser, Whitehouse Station, NJ (US); Srinivasan Chakrapani, Bridgewater, NJ (US); Munirathna Padmanaban, Bridgewater, NJ (US); Ralph R. Dammel, Bangkok (TH)

(21) Appl. No.: 12/915,950

(22) Filed: Oct. 29, 2010

(51) Int. Cl. H01L 21/311; G03F 7/42

(52) U.S. Cl. 438/694; 510/176; 257/E21.255

(57) ABSTRACT

The invention relates to an edge bead remover composition for an organic film disposed on a substrate surface, comprising an organic solvent and at least one polymer having a contact angle with water greater than 70°. The invention also relates to a process for using the composition as an edge bead remover for an organic film.

The present invention relates to the field of microelectronics, such as integrated circuits, and more particularly to compositions and methods for removing photoresist compositions from the surfaces of substrates, used in the fabrication of integrated circuits. The invention relates to compositions and methods for providing residue free photoresist or other coatings during the exposure process. The composition and process is particularly suitable for 193 nm immersion lithography.

Generally, the fabrication of integrated circuits involves steps for producing polished silicon wafer substrates, steps for imaging integrated circuit pattern geometries on the various wafer surfaces, and steps for generating the desired pattern on the wafer.

The imaging process involves the use of photoresists applied to the wafer surface. Photoresists are compositions which undergo change in response to light of particular wavelength such that imagewise exposure of the photoresist through a suitable patterned mask, followed by development to remove exposed or non-exposed portions of the photoresist, leaves on the substrate a pattern of photoresist which replicates either the positive or negative of the mask pattern, and which thus permits subsequent processing steps (such as deposition and growth processes for applying various layers of semiconductive materials to the wafer and etching-masking processes for removal or addition of the deposited or grown layers) to be carried out in the desired selective pattern.

The photoresists used in the imaging process are liquid compositions of organic light-sensitive materials which are either polymers or are used along with polymers, dissolved in an organic solvent. Critical to the effectiveness of the selective light exposure and development in forming a photoresist pattern on the wafer substrate, is the initial application of the photoresist composition in a thin layer of essentially uniform thickness on the substrate, coating processes used in the industry include spin-coating, spray coating, dip coating or roller coating. Spin-coating is the preferred process in the industry.

Despite its widespread use, certain undesirable results also accompany spin-coating. Thus, owing to the surface tension of the photoresist composition, some of the photoresist may wick around to and coat the back side edge of the wafer during the spin-coating process. Also, as the spin-coating process progresses, the photoresist becomes progressively more viscous as solvent evaporates therefrom and photoresist being spun off the wafer in the later stages of the process can leave fine whiskers (“stringers”) of photoresist which dry on the edge of the wafer. So too, as the photoresist continues to dry and increase in viscosity during the spin-coating process, excess photoresist is less likely to leave the wafer and instead builds up as an edge-bead at the outer rim of the wafer surface. These coating-related problems can cause significant difficulties in the overall integrated circuit fabrication process. Photoresist on the back side of the wafer can be deposited elsewhere and cause contamination, and also prevents the wafer from lying flat on ultraflat surfaces, thereby affecting focus, alignment, planarity, and the like, in subsequent imaging steps. Whiskers on the wafer edges can easily break off in subsequent processing steps and cause particulate contamination in virtually all of the manufacturing equipment. Finally, the edge-bead leads to a distorted surface which can greatly affect focus, alignment, planarity and the like. Edge bead results from certain characteristics of the photoresist coating process. Accordingly, in the edge bead remover process, a remover composition is used to remove any unwanted photoresist from the edge and backside of the wafer. Edge bead can form from any solvent based coating during the spin coating process, such as photoresist, antireflective coatings, underlayer, etc.

The art is aware of the problems associated with residual coating at the edges and sides of the wafer, and generally seeks to overcome them by application at the edge of the wafer of a small stream of a solvent for the coating so as to dissolve and remove the unwanted residue. In many cases, the solvent stream is applied to the backside edge of the wafer and is permitted to wick around by capillary action to the front edges so as to remove backside edge residue, whiskers and edge bead. With certain newer equipment, it is possible to apply the solvent stream from both front and back sides of the wafer simultaneously. In all cases, the object essentially is to remove from the wafer a strip of photoresist which is adhered to the wafer sides, the back surface outer edges of the wafer, and the outer edges of the front surface of the wafer, to leave as defect-free a film as possible. The problem of photoresist edge bead is particularly severe for immersion lithography and in the use of top coats. Typically, since a liquid is used between the photoresist layer and the exposure lens in the exposure step of immersion lithography, there is a greater tendency for any particulate matter to be pulled from the edge and circulate between the lens and the photoresist film and thus possibly leading to defects. The photoresist film may be coated over a spin-coated organic antireflective coating, and the antireflective coating may also be treated with an edgebead remover prior to baking.

The present invention relates to a composition comprising organic solvent(s) and a hydrophobic compound which is capable of cleanly removing the edge bead from an organic film without leaving particles, especially for immersion lithography. Water medium used during immersion exposure can cause particles from the edgebead to form over the film. The novel composition comprises organic solvent(s) and a hydrophobic polymer, and optionally a surfactant. The polymer has a contact angle with water of greater than 70°. The present invention also relates to a process of using the novel composition in removing the edge bead from a coated film and forming a thin protective coating on the edge of the coated substrate of the order of 1 mm to 10 mm inwards from the edge of the wafer, this is, on the rim of the substrate. The polymer coating forms only on the rim and not over all the substrate. The organic film may be a photoresist, antireflective coating film or underlayer.

### SUMMARY OF THE INVENTION

The present invention relates to an edge bead remover composition for an organic film coated on a substrate surface, comprising at least one organic solvent and at least one polymer, where the polymer has a contact angle with water of greater than 70°, and where the organic solvent is capable of dissolving the film. The invention further relates to a process for applying the novel composition as an edge bead remover.

### DETAILED DESCRIPTION OF THE INVENTION

The present invention relates to an edge bead remover composition for an organic film coated on a substrate surface, comprising at least one organic solvent and at least one hydrophobic polymer, where the polymer has a contact angle with water of greater than 70°, and where the organic solvent is capable of dissolving the organic film. The contact angle of the hydrophobic polymer may be greater than 80° or range from between 80° and 95°. The invention further relates to a process for applying the novel composition as an edge bead remover. The edge bead may form a film on the rim of the substrate of the order of 1-10 mm or 1-5 mm, and where the edge bead is removed and a coating of the hydrophobic polymer formed on the outer rim of the substrate. The hydrophobic polymer may be exemplified by a fluorinated polymer and a silicon containing polymer. The organic film may be a photoresist or antireflective coating film or underlayer film.

In one embodiment of the novel invention, the invention relates to an edge bead remover composition for an organic layer comprising an organic solvent or mixture of organic solvents, and a fluorinated polymer. In one embodiment of the polymer, the fluorinated polymer is soluble in an aqueous alkaline solution. The fluorinated polymer is not water soluble. A film of the fluorinated polymer has a contact angle with water of greater than 70° or greater than 80°. The contact angle may range from between 80° and 95°. The polymer may be a fluoroalcohol polymer. The present invention also relates to a process of using the novel composition in removing the edge bead formed by the organic coating. The edge bead remover is capable of forming a very thin protective film at the edge of the photoresist coated substrate. The edge bead remover composition is capable of dissolving the organic film. In one embodiment the solvent may be selected from a group consisting of cycloaliphatic ketone (such as cyclopentanone and cyclohexanone) propyleneglycol methyl ether (PGME), ethyl lactate, propyleneglycol methyl ether acetate (PGMEA), and mixtures thereof. The fluorinated polymer which is alkali soluble may have a dissolution rate greater than 5 nm/min or greater than 10 nm/min in an aqueous alkaline developer such as 0.26 N tetramethylammonium hydroxide (TMAH) aqueous solution.

The present invention relates, in one embodiment, to an edge bead remover composition and comprises at least one organic solvent and a fluorinated polymer. The fluorinated polymer of the present invention comprises a fluorinated moiety for hydrophobicity and a moiety which provides alkaline solubility. The fluorinated polymer can be a polymer which comprises a group selected from fluoroalcohol, fully fluorinated alkyl group, partially fluorinated alkyl group, fluorinated alkylene, acidic alcohol and mixtures thereof. The fluorination provides hydrophobicity to the polymer. The alkaline solubility may be provided by an acidic alcohol group (such as phenolic group, fluoroalcohol group) or sulfonamide group or a carboxylic acid group. The fluorinated polymers could be acrylate type of polymer with pendant fluorination, or polymers with a cycloaliphatic backbone (such as polymers derived from norbornene hexafluoroalcohol) or fluorinated backbone polymers.

The fluorinated polymer may comprise a unit of the following structure 1,

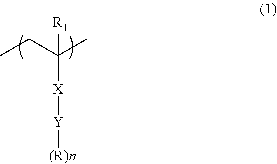

where R₁ is hydrogen or C₁-C₄ alkyl group; X is selected from a direct valence bond, oxy(—O—), carbonyl (—C(O)—), oxycarbonyl (—O—(CO)—), carbonyloxy(—(CO)—O—), and carbonate(—O—(CO)—O—) group; Y is an C₁-C₁₂ alkylene group spacer group, such as linear or branched C₁-C₁₂ alkylene, C₁-C₁₂cycloalkylene or
C₁-C₁₂bicycloalkylene spacer group; R is a fluorinated group such as fluoroalkyl group or fluoroalcohol group, and n=1-6. The fluoroalkyl may be fully or partially fluorinated C₁-C₁₂alkyl group.

In one embodiment of the alkali soluble fluorinated polymer, the unit within the polymer may comprise a fluoroalcohol group and may be of structure 2,

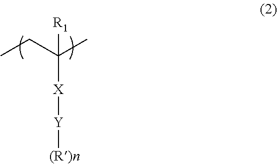

where R₁ is hydrogen or C₁-C₄ alkyl group; X is selected from a direct valence bond, oxy(—O—), carbonyl (—C(O)—), oxycarbonyl (—O—(CO)—), carbonyloxy(—(CO)—O—), and carbonate(—O—(CO)—O—) group; Y is an C₁-C₁₂ alkylene group spacer group, such as linear or branched C₁-C₁₂ alkylene, C₁-C₁₂cycloalkylene or C₁-C₁₂bicycloalkylene spacer group; R′ is a fluoroalcohol group, such as. C(CₘF₂ₘ₊₁)₂OH where m=1-8, and n=1-6. Specific example of R′ is —C(CF₃)₂OH. The value of n may be 1, or 2, or 3, or 4, or 5. The fluoroalcohol polymer may comprise different variations of the unit of structure 2. The fluoroalcohol polymer may further comprise units other than those of structure 2. In one embodiment of the unit, X is carbonyloxy(—(CO)—O—). In one embodiment the fluoroalcohol polymer is an acrylate or methacrylate polymer.

One embodiment of the fluoroalcohol polymer useful for this invention may comprise the units described in structure 3,

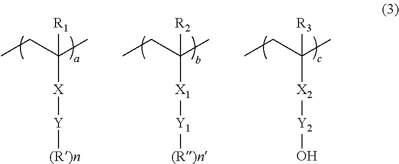

where R₁, R₂ and R₃ are independently selected from hydrogen and C₁-C₄ alkyl group; X, X₁ and X₂ are independently selected from direct valence bond, oxy(—O—), carbonyl(—C(O)—), oxycarbonyl (—O—(CO)—), carbonyloxy(—(CO)—O—), and carbonate(—O—(CO)—O—) group; Y and Y₁ are independently selected from a C₁-C₁₂ alkylene spacer group such as C₁-C₁₂ alkylene, C₁-C₁₂cycloalkylene or C₁-C₁₂bicycloalkylene spacer group; Y₂ is an arylene or aminoarylene moiety which may be further substituted, such as phenylene or substituted phenylene, N(H)arylene, N(H) substituted phenylene; R′ and R″ are independently fluoroalcohol group, such as C(CₘF₂ₘ₊₁)₂OH, m=1-8; n=1-6 and n′=1-6, where the units a and b are different from each other when present together, and a, b and c are the mole ratio of the different units and a can range from 5-100 mole %, b can range from 0-50 mole % and c can range from 0-90 mole %. In one embodiment a can range from 50-80 mole %, in another embodiment b can range from 20-50 mole % and in yet another embodiment c can range from 20-90 mole %. Also, mixtures of such polymers could be used. In one embodiment the polymer comprises units a and c, and not b. In one embodiment the polymer comprises units a and b, and not c. In one embodiment the polymer comprises units a, b and c, providing a and b are different.

An example of the fluoroalcohol polymer is give in structure 4,

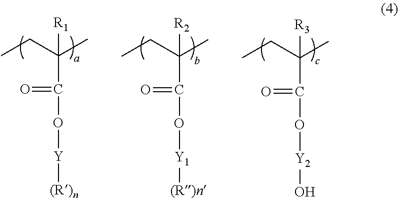

where R₁, R₂ and R₃ are independently <selected from hydrogen and C₁-C₄ alkyl group; Y and Y₁ are independently selected from an C₁-C₁₂ alkylene group spacer group such as C₁-C₁₂ alkylene, C₁-C₁₂cycloalkylene or C₁-C₁₂bicycloalkylene spacer group; Y₂ is an arylene or aminoarylene moiety which may be further substituted, such as phenylene or substituted phenylene, N(H)arylene, N(H) substituted phenylene; R″ and R″ are independently fluoroalcohol group, such as C(CₘF₂ₘ₊₁)₂OH where m=1-8; n=1-6, n′=1-6, where the units a and b are different from each other when both are present, and a, b and c are the mole ratio of the different units and a can range from 5-100 mole %, b can range from 0-50 mole % and c can range from 0-90 mole %. In one embodiment a can range from 50-80 mole %, in another embodiment b can range from 50-80 mole % and in yet another embodiment c can range from 50-90 mole %. Also, mixtures of such polymers could be used. In one embodiment the polymer comprises units a and c, and not b. In one embodiment the polymer comprises units a and b, and not c. In one embodiment the polymer comprises units a, b and c. Examples of unit c are monomers derived from hydroxystyrene, 4-hydroxyphenylmethacrylate, N(4-hydroxyphenyl)aminoethylmethacrylate, etc.

In the above definitions and throughout the present specification, unless otherwise stated the terms used are described below.

Alkyl means linear, branched, cyclic alkyl or mixtures thereof having the desirable number of carbon atoms and valence. The alkyl group is generally aliphatic and may be cyclic or acyclic (i.e. noncyclic). Suitable acyclic groups can be methyl, ethyl, n- or iso-propyl, n-,iso, or tert-butyl, linear or branched pentyl, hexyl, heptyl, octyl, decyl, dodecyl, tetradecyl and hexadecyl. Unless otherwise stated, alkyl refers to 1-10 carbon atom moieties. The cyclic alkyl groups may be mono cyclic or polycyclic and may be further substituted with linear or branched alkyl groups. Suitable example of mono-cyclic alkyl groups include substituted cyclopentyl, cyclohexyl, and cycloheptyl groups. The substituents may be any of the acyclic alkyl groups described herein. Suitable bicyclic alkyl groups include substituted bicyclo[2.2.1]heptane, bicyclo[2.2.2]octane, bicyclo[3.2.1]octane, bicyclo[3.2.2]nonane, and bicyclo[3.3.2]decane, and the like. Examples of tricyclic alkyl groups include tricyclo[5.4.0.0.^{2,9}]undecane, tricyclo[4.2.1.2.^{7,9}]undecane, tricyclo[5.3.2.0.⁴9]dodecane, and tricyclo[5.2.1.0.^{2,6}]decane. As mentioned herein the cyclic alkyl groups may have any of the acyclic alkyl groups as substituents.

Alkylene groups are multivalent alkyl groups derived from any of the alkyl groups mentioned hereinabove. When referring to alkylene groups, these include linear alkylene, an branched alkylene chain substituted with (C₁-C₆)alkyl groups in the main carbon chain of the alkylene group, or a substituted or unsubstituted alkylene. Alkylene groups can also include one or more alkyne groups in the alkylene moiety, where alkyne refers to a triple bond. Essentially an alkylene is a divalent hydrocarbon group as the backbone. Accordingly, a divalent acyclic group may be methylene, 1,1- or 1,2-ethylene, 1,1-, 1,2-, or 1,3 propylene, 2,5-dimethyl-hexene, 2,5-dimethyl-hex-3-yne, and so on. Similarly, a divalent cyclic alkyl group may be 1,2- or 1,3-cyclopentylene, 1,2-, 1,3-, or 1,4-cyclohexylene, and the like. A divalent tricyclo alkyl groups may be any of the tricyclic alkyl groups mentioned herein above. Multivalent alkylene groups may be used.

Aryl groups contain 6 to 24 carbon atoms including phenyl, tolyl, xylyl, naphthyl, anthracyl, biphenyls, bis-phenyls, tris-phenyls and the like. These aryl groups may further be substituted with any of the appropriate substituents e.g. alkyl, alkoxy, acyl or aryl groups mentioned hereinabove. Similarly, appropriate polyvalent aryl groups as desired may be used in this invention. Representative examples of divalent aryl groups include phenylenes, xylylenes, naphthylenes, biphenylenes, and the like.

More specifically the fluoroalcohol polymer may comprise units as shown in structures 5-7, where k, l, p, q, r and s are mole ratios of the units in the polymer. In structure 5, k may range from 55-75 mole % and the sum of k and l adding up to 100%; in structure 6, p may range from 60-80 mole % and the sum of p and q adding up to 100 mole %; and in structure 7, r may range from 60-85 mole % and the sum of r and s adding up to 100%.

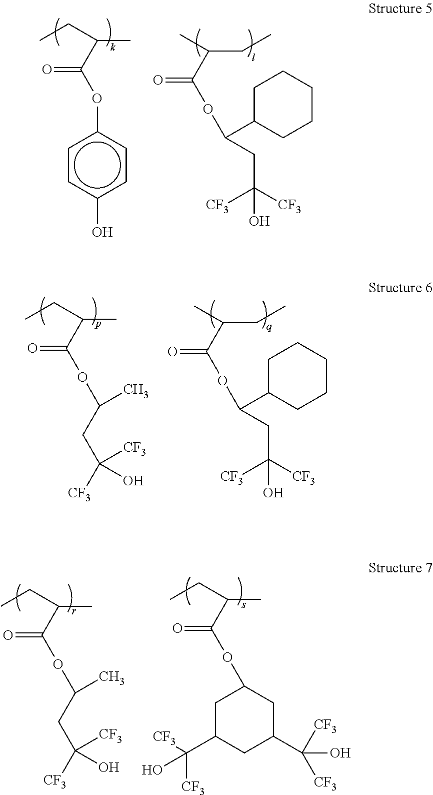

Another example of the fluorinated polymer comprises the units of structure 8, where unit d provides hydrophobicity and unit e provides alkaline solubility,

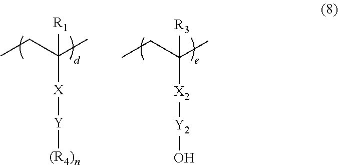

where R₁ and R₃ are independently selected from hydrogen and C₁-C₄ alkyl group; X, and X₂ are independently selected from direct valence bond, oxy(—O—), carbonyl(—C(O)—), oxycarbonyl (—O—(CO)—), carbonyloxy(—(CO)—O—), and carbonate(—O—(CO)—O—) group; Y is a C₁-C₁₂ alkylene spacer group such as C₁-C₁₂ alkylene, C₁-C₁₂cycloalkylene or C₁-C₁₂bicycloalkylene spacer group; Y₂ is an arylene or aminoarylene moiety which may be further substituted, such as phenylene or substituted phenylene, N(H)arylene, N(H) substituted phenylene R₄ is a partially or fully fluorinated C₁-C₁₂alkyl group, n=1-6, and where d and e are the mole ratio of the units present in the polymer. The unit d can range from 5-95 mole %, e can range from 5-95 mole %. In one embodiment d can range from 50-80 mole %, in another embodiment a can range from 20-50 mole %. Other comonomeric units may also be present, such as the unit of structure 2. Also, mixtures of such polymers could be used. Examples of unit d are monomers derived from trifluoroethylmethacrylate, pentafluoropropylmethacrylate etc. Examples of unit e are monomers derived from hydroxystyrene, 4-hydroxyphenylmethacrylate, N(4-hydroxyphenylethyl methacrylamide), etc.

Another example of the polymer useful for the present invention is a silicon containing polymer, such as a polysiloxane and polysilsesquioxane polymer. Polysiloxane and polysilsesquioxane polymers are available from Gelest Inc. (612 William Leigh Drive, Tullytown, Pa.), and are hydrophobic, giving a contact angle in water of greater than 70°.

The polymer in the present novel composition can have a weight average molecular weight, Mw, ranging from 1,000 to 100,000, or from 15,000-50,000. The polymer has a water contact angle greater than 70° or greater than 80° or in the range from 80° to 95°, thus making the surface at the edges hydrophobic prior to exposure to immersion lithography. The contact angle has been found to have similar values with or without a post applied bake (PAB). The PAB is typically around 110° C./60 s to essentially remove the solvent. High values (greater than or equal to 70°) of contact angle at the edges of the wafer, obtained from the hydrophobic polymer of the present invention, will eliminate any antireflective coating particles or photoresist flakes from being dragged from the edges by the moving aqueous media towards the photoresist coating being imaged during immersion exposure step. The water contact angle may be measured as is known in the art, typically using VCA 2500XE (Video contact angle system) from AST Products, Inc., using OmmiSolv water from EM Science. The soft baked film, typically around 110° C./60 s, formed from the fluoroalcohol polymer has a dissolution rate greater than 5 nm/minute in aqueous 026 N tetramethylammonium hydroxide solution, or greater than 10 nm/minute in aqueous 0.26 N tetramethylammonium hydroxide solution. Further the solubility may be greater than 14 nm/minute in aqueous 0.26 N tetramethylammonium hydroxide solution. The hydrophobic polymer film formed from the novel composition may or may not be soluble in an aqueous alkaline solution.

The novel composition comprises an organic solution of the polymer in an organic casting solvent. The composition comprises the polymer in the range of 0.1 to 10 wt % of the total composition. The composition is capable of forming a film of the polymer on the edge of the substrate of less than 20 nm or less than 19 nm or less than 18 nm. The polymers could also form monomolecular films. The polymer film may be in the range of about 1-20 nm or 1-19 nm or 1-18 nm. The polymer film may be in the range of monomolecular film-20 nm or monomolecular film-19 nm or monomolecular film-18 nm. The organic solvents may be selected from any solvent capable of dissolving the polymer and also the photoresist film. Typical solvents are cycloaliphatic ketones (such as cyclopentanone and cyclohexanone) ethyl lactate, propyleneglycol methyl ether (PGME), propyleneglycol methyl ether acetate (PGMEA), mixtures thereof. Further additives, such as surfactants may be added. The composition may consist of organic solvent(s), hydrophobic polymer and optionally a surfactant.

The novel composition may be free of any crosslinker and any thermal acid generator. The novel composition may be free of any absorbing chromophore group, where the chromophore group is one which absorbs radiation used to expose the imaging photoresist. The novel composition may comprise an absorbing chromophore group, where the chromophore group is one which absorbs radiation used to expose the imaging photoresist. Chromophore groups may be aryl groups such as phenyl, where the phenyl may be substituted or unsubstituted. The novel composition may be free of any alkaline compound. The composition may consist essentially of the fluorinated polymer as described herein, organic solvent(s) as described herein, and optionally a surfactant.

The novel composition may be used in a process for removing the photoresist edge bead, where the process comprises the steps of forming a photoresist film on a substrate; and, applying the novel edge bead remover composition of the present invention. The general application of the edge bead remover to remove the edge bead is known in the art. The application of the edge bead remover composition of the present invention dissolves the photoresist film at the edges and further forms a thin coating of the hydrophobic polymer on the edge, especially where the novel composition is in contact with the photoresist film. The entire photoresist film is not coated with the fluorinated polymer. The thin coating of the fluorinated polymer prevents particles from being dragged from the edge and over the photoresist film during exposure. The process may further comprise steps of imagewise exposing the photoresist film; developing the photoresist film; and optionally heating the film before or after the developing step. The process may further comprise a step of forming a film of an organic spin coatable antireflective coating or multiple spin coatable antireflective coatings below the photoresist film prior to forming the photoresist film, and the antireflective coating film(s) may also be treated with an edge bead remover, where this edge bead remover could be any edge bead remover but could also be the present novel composition. The imaging process may be immersion lithography as is known in the art. Any known photoresist and antireflective coating known in the art may be used. Thus, in one embodiment, the substrate is coated with at least one antireflective coating, treated with an edgebead remover, a photoresist film is formed over the antireflective coating(s), and the novel edge bead remover composition of the present invention is then applied to the coatings). The process may further comprise steps of imagewise exposing the photoresist film using immersion lithography; developing the photoresist film; and optionally heating the film before or after the developing step.

Each of the US patents and patent applications referred to above are incorporated herein by reference in its entirety, for all purposes. The following specific examples will provide detailed illustrations of the methods of producing and utilizing compositions of the present invention. These examples are not intended, however, to limit or restrict the scope of the invention in any way and should not be construed as providing conditions, parameters or values which must be utilized exclusively in order to practice the present invention. Unless otherwise stated the ranges and numerical values are based on weights.

### EXAMPLES

### Monomers

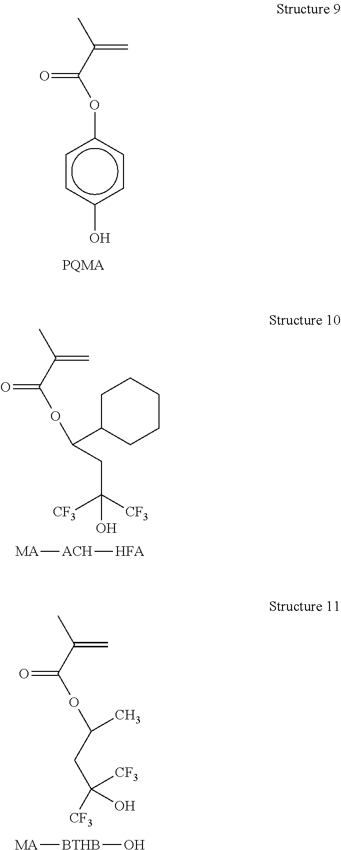

AZ 300MIF Developer available from AZ Electronic materials USA Corp., 70, Meister Ave., Somerville, N.J.

### Example 1

### Synthesis of Polymers A-C

Polymer A which is PQMA/MA-ACH—HFA (50/50 molar monomer feed);
Polymer B which is MA-BTHB—OH/MA-ACH—HFA (25/75 molar monomer feed);
Polymer C which is MA-3,5-HFA-CHOH/MA-ACH—HFA (25/75 molar monomer feed).

In a 250 mL flask equipped with a reflux condenser, a thermometer, under nitrogen, the monomers, PQMA (5.73 g) and MA-ACH—HFA (12.26 g) (50150 molar monomer feed) AIBN (0.87 g) and tetrahydrofuran (106.14 g) were purged with nitrogen and heated to reflux for 5 hours. The polymerization was capped with methanol (3 mL), then precipitated into hexanes (750 mL). The precipitated polymer A was redissolved in tetrahydrofuran (60 g), and precipitated in acetone (5%)/(95%)hexanes (total 450 mL) once again. The precipitated solid was dried in an oven at 45° C. for 48 hours to give a white solid polymer A (24.6 g, 94.2%). The molecular weight was measured by gel permeation (GPC) chromatography and given in Table 1.

The above procedure was repeated to give Polymer B and C with the molar feed ratio as below:
Polymer B which is MA-BTHB—OH/MA-ACH—HFA (25/75 molar monomer feed and,
Polymer C which is MA-3,5-HFA-CHOH/MA-ACH—HFA (25/75 molar monomer feed).

### Example 2

Each of the polymers A, B and C were dissolved separately in the EBR solvent PGMEA and solutions were made at a concentration of 0.4 wt % (to give a 14-19 nm film thickness (FT)), and, 0.2 wt % (to give <10 nm Film Thickness, 8 nm and less by varying the spin speed). The samples were coated separately on a Suss ACS300 Coater on an 8″ Silicon wafer and subjected to a post-applied bake (PAB) of 110° C./60 s. The contact angle of the polymer surfaces was measured. One wafer with the Polymer A solution did not have a PAB and its contact angle was measured after spin coating. Contact angle measurements were made using VCA 2500XE (Video contact angle system) from AST Products, Inc., using OmniSolv water from EM Science. Each contact angle measurement was an average of 6 readings (each reading gave a pair of measurements). Developer solubility was measured by using an AZ® 300 MIF developer (0.26N) puddle for 60 s (23° C.). Film thickness (FT) differences between FT values before and after the developer puddle was applied were used for determining the developer solubility. The results are given in Table 1.

TABLE 1
Summary of the properties of the films made from the polymer solutions

| | | | | | | Static |
|---|---|---|---|---|---|---|
| | | | | | | contact |
| | Molecular | Film | Static | Complete | Development | Angle |
| | Weight | Thickness | contact | Developer | speed | (no |
| Polymer | (Mw) | (nm) | Angle | Solubility | nm/min | PAB) |
| Polymer A | 16461 | 14.6 | 85 | yes | >14.6 | N.A |
| Polymer A | 16461 | 8.4 | 84.6 | yes | >14.6 | 83 |
| | | | | | | (9.7 nm) |
| Polymer A | 16461 | ~1.5 | 84.8 | yes | >14.6 | N.A |
| Polymer B | 9142 | 14 | 89.3 | yes | >14 | N.A |
| Polymer C | 10,076 | 18.8 | 86.3 | yes | >18.8 | N.A |

### Example 3

A wafer is coated and baked with a 193 nm antireflective coating composition (typically to give around >70 nm film) and after EBR treatment baked at over 200° C. to give a uniform film of the bottom antireflective coating. Then, a photoresist composition is coated onto the bottom antireflective coating film and subjected to the EBR treatment using any of the compositions of Example 2. Subsequently, the wafer is subjected to a soft bake (or PAB) of 100° C./60 s and exposed to 193 nm immersion exposure using water as the immersion medium. The exposed wafer is then subjected to a post exposure bake (PEB) of 110° C./60 s. Then the exposed wafer is developed in the AZ 300MIF Developer for 60 s. The exposed and developed wafer is inspected for defects related to immersion conditions like EBR-related defects or water marks and so on.

### Example 4

The following polysiloxane T-resin was tested for contact angle improvement of EBR-treated wafers. In this example, the polymer was prepared in PGMEA as a 0.75 wt. % solution. This T-resin has an empirical formula of RSiO_{1.5}. One of the representations of the T-resins can be

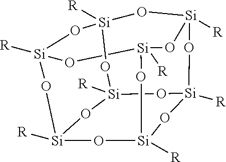

The above polymer, where R is phenyl, was tested for its contact angle. The SCA with DI water was 76.8° for a film thickness of 14.3 nm and 76.2 at 6.5 nm film thickness. The resin was obtained from Gelest Inc. at 612 William Leigh Drive, Tullytown, Pa.

1. An edge bead remover composition for an organic film coated on a substrate surface, comprising at least one organic solvent and at least one polymer with a contact angle with water of at least 70°, and where the organic solvent is capable of dissolving the organic film.

2. The composition of claim 1 where the polymer is selected from a fluorinated polymer.

3. The composition of claim 1 where the polymer is selected from a silicon containing polymer.

4. The composition of claim 1 where the polymer is an alkali soluble fluorinated polymer.

5. The composition of claim 1 where the polymer is an alkali soluble fluorinated polymer having a dissolution rate greater than 5 nm/minute in an aqueous 0.26 N tetramethylammonium hydroxide solution,

6. The composition of claim 1, where the polymer has a contact angle with water in the range of 80° and 95°.

7. The composition of claim 1, where the polymer comprises a unit of structure 1, 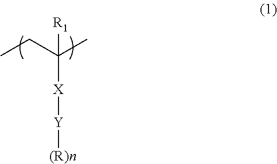
where R₁ is hydrogen or C₁-C₄ alkyl group; X is selected from direct valence bond, oxy(—O—), carbonyl (—C(O)—), oxycarbonyl (—O—(CO)—), carbonyloxy(—(CO)—O—), and carbonate(—O—(CO)—O—) group; Y is an C₁-C₁₂alkylene group spacer group; R is a fluorinated group, and n=1-6.

8. The composition of claim 2, where the fluorinated group is fluoroalkyl group or fluoroalcohol group.

9. The composition of claim 1, where the polymer comprises a unit of structure 2, 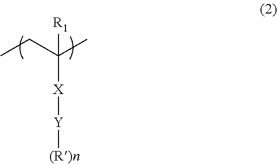
where R₁ is hydrogen or C₁-C₄ alkyl group; X is selected from a direct valence bond, oxy(—O—), carbonyl (—C(O)—), oxycarbonyl (—O—(CO)—), carbonyloxy(—(CO)—O—), and carbonate(—O—(CO)—O—) group; Y is an C₁-C₁₂ alkylene group spacer group; R′ is a fluoroalcohol group, and n=1-6.

10. The composition of claim 8, where the fluoroalcohol group is C(CₘF₂ₘ₊₁)₂OH where m=1-8,

11. The composition of claim 1 where the polymer comprises a unit(s) of structure 3 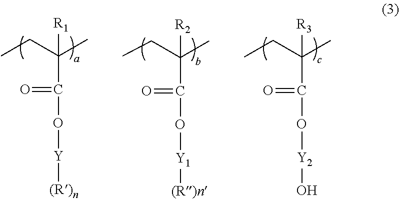
where R₁, R₂ and R₃ are independently selected from hydrogen and C₁-C₄ alkyl group, X, X₁ and X₂ are independently selected from direct valence bond, oxy(—O—), carbonyl (—C(O)—), oxycarbonyl (—O—(CO)—), carbonyloxy(—(CO)—O—) and carbonate(—O—(CO)—O—) group, Y₂ is an aryl moiety, Y and Y₁ are independently selected from a C₁-C₁₂ alkylene group spacer group and different from each other, R′ and R″ are independently fluoroalcohol group, n=1-8, n′=1-8 and a, b and c are the mole ratio of the different units, where a can range from 5-100 mole %, b can range from 0-50 mole % and c can range from 0-90 mole %.

12. The composition of claim 11, where in the polymer, a can range from 50-80 mole %, b can range from 50-80 mole % and c can range from 50-90 mole %.

13. The composition of claims 1, where the solvent is selected from cyclopentanone, cyclohexanone, ethyl lactate, propyleneglycol methyl ether, propyleneglycol methyl ether acetate, mixtures thereof.

14. The composition of claim 1, where the composition is free of crosslinker.

15. The composition of claim 1, where the composition is free of thermal acid generator or photoacid generator.

16. The composition of claim 1, where the composition is free of a chromophore group.

17. A process for removing an edge bead comprising the steps of:
a) forming an organic film on a substrate; and,
b) applying composition of claim 1 as an edge bead remover to the organic film.

18. A process for removing an edge bead and forming an image in the photoresist comprising the steps of:
a) forming a photoresist film on a substrate;
b) applying composition of claim 1 as an edge bead remover to the organic film;
c) image wise exposing the photoresist film;
d) developing the photoresist film; and
e) optionally, heating the film before or after the developing step.

19. The process of claim 18, where the imagewise exposure is carried out by immersion scanner.

20. The process of claim 17, where the organic film is an antireflective coating.

21. The process of claim 17, where a film of the polymer is formed over the rim of the organic film after the edge bead removal step (b).
